(19) United States
(12) Patent Application Publication
(10) Pub. No.: US 2008/0101428 A1
(43) Pub. Date: May 1, 2008

(54) LASER-POWER CONTROL METHOD, AND LASER DRIVING DEVICE AND OPTICAL DISC APPARATUS USING THE METHOD

(75) Inventors: Toshiaki Ohgushi, Tokyo (JP); Kazuto Kuroda, Tokyo (JP); Takashi Usui, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 11/929,717

(22) Filed: Oct. 30, 2007

(30) Foreign Application Priority Data
Oct. 31, 2006 (JP) 2006-296850

(51) Int. Cl. H01S 5/00; G11B 7/125

(52) U.S. Cl. 372/38.02; 369/53.26

(57) ABSTRACT

In a laser-power control method, a power of laser light emitted from a laser-light emitting element and a driving current for driving the laser-light emitting element are detected. An approximate expression indicating a driving-current to light-power characteristic of the laser-light emitting element is updated on the basis of the detected light power and the detected driving current while sequentially increasing accuracy. A command driving current corresponding to a target light power is calculated by using the updated approximate expression. The laser-light emitting element is driven on the basis of the calculated command driving current so as to output the target light power.

### CROSS-REFERENCE TO RELATED APPLICATIONS

This application claims the benefit of priority of Japanese Patent Application No. 2006-296850, filed Oct. 31, 2006, the entire contents of which are incorporated herein by reference.

### BACKGROUND

1. Field

The present invention relates to a laser-power control method and to a laser driving device and an optical disc apparatus using this method. More particularly, the present invention relates to a laser-power control method for a writable and readable optical disc, and to a laser driving device and an optical disc apparatus using this method.

2. Description of the Related Art

In a recordable optical disc such as a CD-R, a CD-RW, a DVD-R, a DVD-RW, a DVD-RAM, an HD DVD-R, an HD DVD-RAM, or an HD DVD-RW, tracks including grooves and lands are provided on a surface of the disc, and marks and spaces corresponding to recording data are formed by irradiating laser light with recording laser power onto the tracks.

In general, a laser diode is used as a laser light source for an optical disc. However, it is known that the power of light emitted from the laser diode varies with temperature and operating time. There is a need to maintain a predetermined power of light emitted from the laser diode in order to form marks and spaces in proper shapes. For that purpose, an optical disc apparatus normally performs laser power control such as APC (auto power control). The laser power control constantly ensures a predetermined light power.

A multi-pulse method is widely used for irradiation of recording laser light. In this method, a plurality of pulses having different power levels are repetitively generated in a short period when forming one recording mark.

In the multi-pulse method, of course, laser power control is also necessary. For example, JP-A 2000-30276 discloses a multi-pulse method using two types of peak powers and one type of bottom power. In this method, one of the peak powers and the bottom power are measured, and the ratio of one power to the other power is obtained. The other peak power is calculated from the obtained ratio and a preset ratio.

As described above, the multi-pulse method has become popular for recent optical discs. In the multi-pulse method, a pulse train is formed by combining a plurality of short pulses (hereinafter sometimes referred to as sub-pulses) having different powers when forming one recording mark. More specifically, short pulses having three different power levels, namely a peak power, an erase power, and a bottom power, are combined relatively frequently in the multi-pulse method.

In order for the laser diode to switch among the three power levels in a short period, three types of driving currents corresponding to the peak power, the erase power, and the bottom power are generated as driving currents for the laser diode, and control is exerted so that these driving currents are switched over a short period.

As described above, the power of light emitted from the laser diode varies with temperature and operating time. This is because the driving-current to light-power characteristic of the laser diode indicating the relationship between the driving current and the light power (hereinafter referred to as an I-L characteristic) varies with temperature and operating time. In general, the I-L characteristic is not linear, and is not shifted in a simple parallel manner according to temperature and operating time. For this reason, the driving currents need to be independently controlled in order to set the peak power, the erase power, and the bottom power at desired values.

The simplest method for realizing this control is to prepare three independent APC loops corresponding to the peak power, the erase power, and the bottom power. Unfortunately, this method has the following problems.

In order to form three independent APC loops, it is necessary to independently measure the powers in each sub-pulse of the pulse train. For this reason, a peak hold circuit and a sample-and-hold circuit need to be provided for each of the peak power, the erase power, and the bottom power. This increases the size of hardware and the cost.

Only sub-pulses corresponding to a head and an end of a recording mark are sometimes formed by sub-pulses (called boost pulses) having a level higher than those of the other sub-pulses. In this case, it is unclear which portion of the sub-pulses including the boost pulses is held by the peak hold circuit. Therefore, precise power measurement is difficult.

Further, since the width of the sub-pulses is considerably short, an optical monitor element, such as a front monitor, for detecting the laser power is required to have a wide band.

The above-described problems have become more pronounced as the density and driving speed of the optical disc increases. In a high-density recordable HD DVD, for example, the pulse width of the sub-pulse is sometimes, approximately equal to ten nanoseconds. In this case, a considerably wide band is necessary for the optical monitor element, and a technical difficulty in realizing the peak hold circuit and the sample-and-hold circuit is increased.

### SUMMARY OF THE INVENTION

The present invention has been made in view of the above-described circumstances, and an object of the present invention is to provide a laser-power control method for a laser that performs recording on an optical disc by a multi-pulse method. In the laser-power control method, a desired laser power can be precisely set without using a high-speed and wide-band circuit element even when the I-L characteristic of the laser is nonlinear, and to provide a laser driving device and an optical disc apparatus using the laser-power control method.

In order to overcome the above-described problems, a laser-power control method according to an aspect of the present invention includes a power detecting step of detecting a power of laser light for recording or reproduction emitted from a laser-light emitting element onto an optical disc; a driving-current detecting step of detecting a driving current for driving the laser-light emitting element; an approximate-expression updating step of updating an approximate expression on the basis of the detected light power and the detected driving current while sequentially increasing accuracy, the approximate expression indicating a driving-current to light-power characteristic of the laser-light emitting element; a command-driving-current calculating step of calculating a command driving current corresponding to a target light power by the updated approximate expression; and a current driving step of driving the laser-light emitting element on the basis of the calculated command driving current so that the laser-light emitting element outputs the target light power.

An optical disc apparatus according to another aspect of the present invention includes a laser-light emitting element configured to emit laser light for recording or reproduction onto an optical disc; a power detecting unit configured to detect a power of the laser light emitted from the laser-light emitting element; a driving-current detecting unit configured to detect a driving current for driving the laser-light emitting element; an approximate-expression updating unit configured to update an approximate expression on the basis of the detected light power and the detected driving current while sequentially increasing accuracy, the approximate expression indicating a driving-current to light-power characteristic of the laser-light emitting element; a command-driving-current calculating unit configured to calculate a command driving current corresponding to a target light power by the updated approximate expression; and a current driving unit configured to drive the laser-light emitting element on the basis of the calculated command driving current so that the laser-light emitting element outputs the target light power.

A laser driving device according to a further aspect of the present invention includes a driving-current detecting unit configured to detect a driving current for driving a laser-light emitting element; and a current driving unit configured to drive the laser-light emitting element on the basis of an input command driving current so that the laser-light emitting element outputs a target light power. An approximate expression indicating a driving-current to light-power characteristic of the laser-light emitting element is updated on the basis of the detected driving current and a power of light emitted from the laser-light emitting element, the power being detected by an external power detecting unit, while sequentially increasing accuracy, and the command driving current is calculated as a driving current corresponding to the target light power by the updated approximate expression.

According to the aspects of the present invention, in the laser-power control method in which recording is performed on an optical disc by a multi-pulse method, a desired laser power can be precisely set without using a high-speed and wide-band circuit element even when the I-L characteristic of the laser is nonlinear.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a structural view showing a configuration of an optical disc apparatus according to an embodiment of the present invention;

FIG. 2 is an explanatory view showing the powers of light emitted from a laser-light emitting element, and a write strategy;

FIG. 3 is a structural view showing a configuration of a laser driving device according to the embodiment of the present invention;

FIG. 4 is a graph showing the I-L characteristic of the laser-light emitting element;

FIG. 5 is a graph showing the I-L characteristics of the laser-light emitting element actually measured at a plurality of temperatures;

FIG. 6 is an explanatory view showing the relationship between an average power and an erase power;

FIG. 7 is a flowchart showing a laser-power control method according to a first embodiment of the present invention;

FIG. 8 is a chart of a write strategy explaining calculation of the duty ratio;

FIG. 9 is a flowchart showing a detailed operation of setting initial parameter values;

FIG. 10 is a structural view showing a configuration of a laser driving device to which a function of finding an average current is added;

FIG. 11 is a flowchart showing a laser-power control method according to a second embodiment of the present invention;

FIG. 12 is a flowchart showing a laser-power control method according to a third embodiment of the present invention;

FIG. 13 is a flowchart showing a laser-power control method according to a fourth embodiment of the present invention;

FIG. 14 is a flowchart showing a laser-power control method according to a fifth embodiment of the present invention;

FIG. 15 is a flowchart showing a laser-power control method according to a sixth embodiment of the present invention; and

FIG. 16 is an explanatory view showing an example of a write strategy including boot pulses.

### DETAILED DESCRIPTION

A laser-power control method, and a laser driving unit and an optical disc apparatus using this control method according to an embodiment of the present invention will be described with reference to the attached drawings.

### (1) Configurations of Optical Disc Apparatus and Laser Driving Device

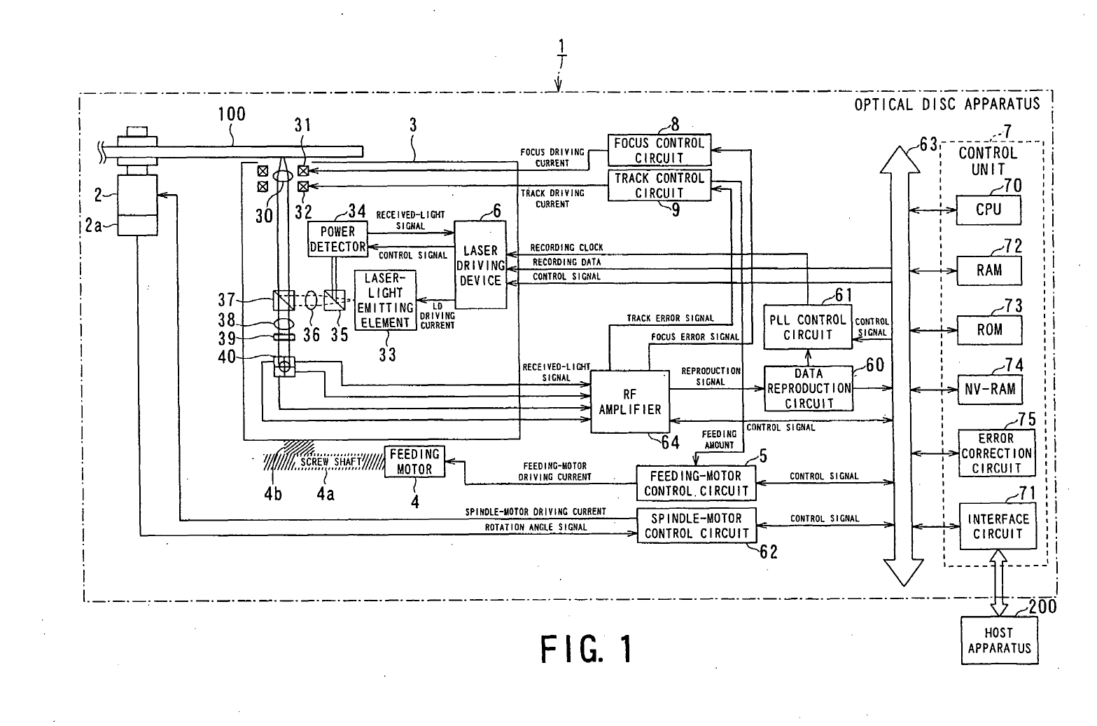

FIG. 1 shows a configuration of an optical disc apparatus 1 according to this embodiment.

An optical disc apparatus 1 records and reproduces information on and from an optical disc 100, such as a DVD (digital versatile disc), that is, an information storage medium. Tracks including concave portions called grooves and convex portions called lands are provided in a spiral form on the optical disc 100. User data is recorded as recording marks by irradiating intensity-modulated laser light along the tracks (only grooves, or grooves and lands).

Data reproduction is performed by irradiating laser light having a read power, which is weaker than the power used for recording, along the tracks and detecting changes in intensity of light reflected by the recording marks on the tracks. Recorded data is erased by irradiating laser light having an erase power stronger than the read power along the tracks so as to crystallize a recording layer.

The optical disc 100 is rotated by a spindle motor 2. A rotation angle signal is supplied from a rotary encoder 2a provided on the spindle motor 2. For example, when the spindle motor 2 makes one rotation, the rotary encoder 2a generates five pulses as the rotation angle signal. The rotation angle and rotation speed of the spindle motor 2 can be detected from the rotation angle signal. A spindle-motor control circuit 62 controls the rotation of the spindle motor 2 on the basis of the detected rotation angle and rotation speed.

Information recording and reproduction for the optical disc 100 are performed with an optical pickup 3. The optical pickup 3 is connected to a feeding motor 4 via a gear 4b and a screw shaft 4a. The feeding motor 4 is controlled by a feeding-motor control circuit 5. The feeding motor 4 is rotated by a feeding-motor driving current from the feeding-motor control circuit 5, and the optical pickup 3 is thereby moved in the radial direction of the optical disc 100.

The optical pickup 3 includes an objective lens 30 supported by a wire or a leaf spring (not shown). The objective lens 30 can be moved in the focusing direction (along the lens optical axis) by driving a driving coil 31, and in the tracking direction (in a direction orthogonal to the lens optical axis) by driving a driving coil 32.

In information recording (mark formation), a laser driving device 6 supplies a driving current for writing to a laser-light emitting element (laser diode) 33 on the basis of recording data supplied from a host apparatus 200, such as a personal computer, via an interface circuit 71 in a control unit 7. In information reading, the laser driving device 6 supplies a driving current for reading, which is smaller than the writing driving current, to the laser-light emitting element 33. A detailed configuration of the laser driving device 6 will be described below.

A predetermined part of laser light emitted from the laser-light emitting element 33 is caused by a half mirror 35 to branch off, and a power detector 34 (sometimes referred to as a front monitor (FM)), such as a photodiode, receives the light part and detects, as a received-light signal, a signal proportional to the amount of the received light part, that is, light power. The detected received-light signal is supplied to the laser driving device 6. According to the received-light signal from the power detector 34, the laser driving device 6 controls the laser-light emitting element 33 so as to emit laser light with a read power, a write power, and an erase power set by the control unit 7.

The laser-light emitting element 33 emits laser light in accordance with a driving current supplied from the laser driving device 6. The laser light emitted from the laser-light emitting element 33 is applied onto the optical disc 100 via a collimator lens 36, a half prism 37, and the objective lens 30.

In an opposite direction, light reflected from the optical disc 100 is guided to a photodetector 40 via the objective lens 30, the half prism 37, a light-collecting lens 38, and a cylindrical lens 39.

For example, the photodetector 40 includes four photosensor cells. Detection signals from the photosensor cells are output to an RF amplifier 64. The RF amplifier 64 processes the signals from the photosensor cells, and generates a focus error signal FE indicating an error from the focus, a tracking error signal TE indicating an error between the center of a beam spot of the laser light and the track center, and a reproduction signal RF serving as a sum signal indicating the sum of the signals from the photosensor cells.

The focus error signal FE is supplied to a focus control circuit 8. According to the focus error signal FE, the focus control circuit 8 generates a focus driving signal, and supplies the focus driving signal to the driving coil 31 for the focusing direction. Consequently, focus servo control is exerted so that laser light is always properly focused on the recording film of the optical disc 100.

The tracking error signal TE is supplied to a track control circuit 9. According to the tracking error signal TE, the track control circuit 9 generates a track driving signal, and supplies the track driving signal to the driving coil 32 for the tracking direction. Consequently, tracking servo control is exerted so that the laser light constantly traces the tracks provided on the optical disc 100.

The focus servo control and tracking servo control described above allow the spot of laser light to precisely trace the tracks on the recording surface of the optical disc 100. As a result, changes of light reflected from pits provided on the tracks of the optical disc 100 corresponding to recording information are precisely reflected in the sum signal RF indicating the sum of the signals output from the photosensor cells, and a high-quality reproduction signal can be obtained. The reproduction signal (sum signal RF) is supplied to a data reproduction circuit 60. The data reproduction circuit 60 reproduces recording data on the basis of reproduction clock signals from a PLL control circuit 61.

When the objective lens 30 is controlled by the track control circuit 9, the feeding motor 4 is driven by the feeding-motor control circuit 5 to control the position of the optical pickup 3 in the radial direction so that the objective lens 30 is placed near a predetermined position on the recording surface of the optical disc 100.

The feeding-motor control circuit 5, the laser driving device 6, the RF amplifier 64, the focus control circuit 8, the track control circuit 9, the data reproduction circuit 60, the PLL circuit 61, and the spindle-motor control circuit 62 are connected to the control unit 7 via a bus 63. The control unit 7 includes a CPU 70 that controls the entire optical disc apparatus 1 according to operation commands supplied from the host apparatus 200 via the interface circuit 71. The CPU 70 uses a RAM 72 as a work area, and executes programs stored in a ROM 73 with appropriate reference to parameters recorded in a nonvolatile memory NV-RAM 74 for the respective units.

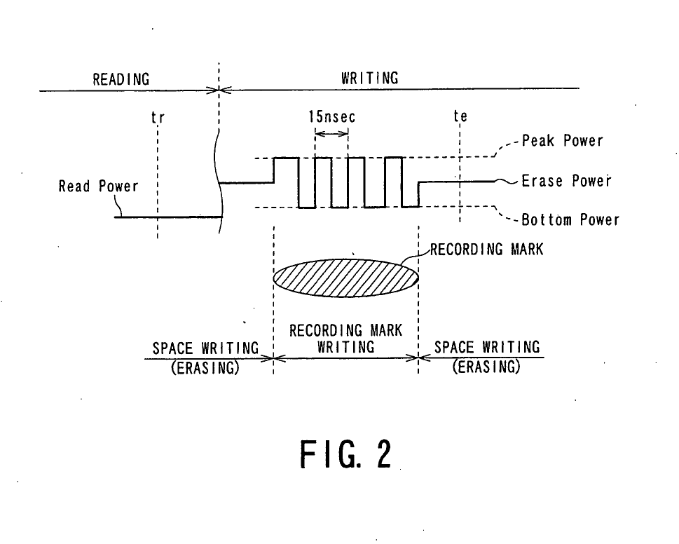

FIG. 2 schematically shows changes in the power of laser light emitted from the laser-light emitting element 33 in the optical disc apparatus 1 according to this embodiment. The optical disc apparatus 1 records data on the optical disc 100 by a multi-pulse method in which a plurality of sub-pulses are generated when forming a recording mark. During data recording (writing), the laser-light emitting element 33 alternately and repetitively generates a light power called a peak power and a light power called a bottom power, and forms a recording mark on the track of the optical disc 100, as shown in FIG. 2. Specifications, such as the number and width of sub-pulses generating the peak power and the bottom power, and combinations thereof are generally called a strategy or a write strategy. The strategy or the write strategy is standardized in accordance with the type of the optical disc 100.

In recent high-density recording media such as recordable HD DVDs, the interval between sub-pulses is considerably short. For example, the interval between the adjacent sub-pulses with the peak power is about 15 nanoseconds, as shown in FIG. 2.

In order to erase recording data, the laser-light emitting element 33 generates an erase power weaker than the peak power so as to crystallize the recording layer of the optical disc 100 and to thereby form a space (that is, erase a recording mark).

In contrast, during data reproduction (reading), the laser-light emitting element 33 continuously generates a light power called a read power. Since the read power is weaker than the erase power, it does not change the phase state of the recording layer.

The peak power, the bottom power, the erase power, and the read power, and the generation timings thereof are controlled by the laser driving device 6.

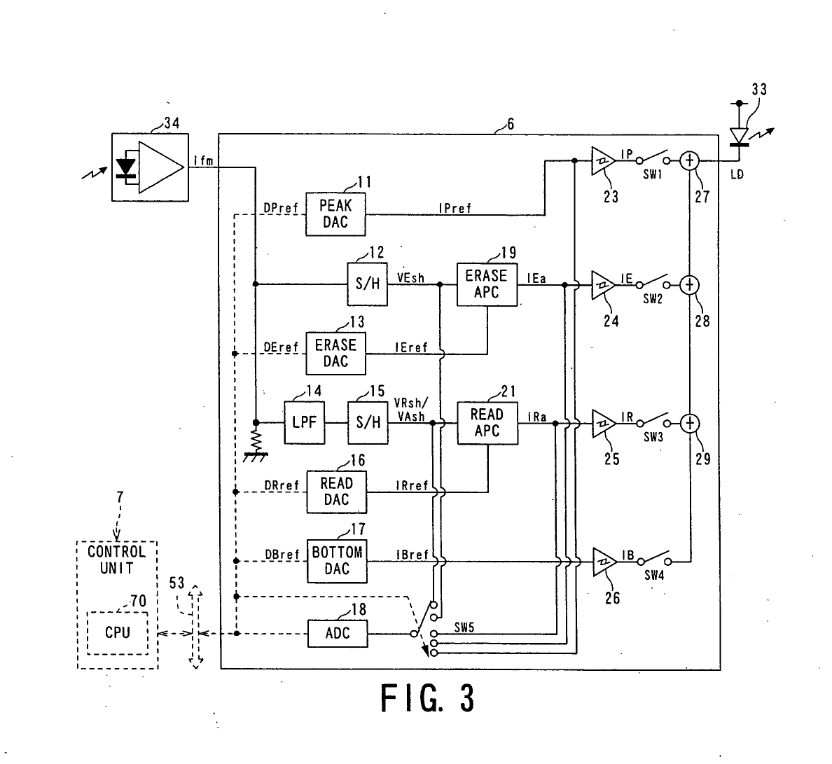

FIG. 3 shows a configuration of the laser driving device 6. The laser driving device 6 includes four systems for independently controlling the above-described four light powers, peak power, bottom power, erase power, and read power. Current amplifiers 23, 24, 25, and 26 are provided on the output sides of the respective systems. The current amplifiers 23, 24, 25, and 26 amplify reference driving currents corresponding to the light powers. The output timings of the amplified driving currents are controlled by switching among switches SW1, SW2, SW3, and SW4 provided in the respective systems. On the most downstream side of the laser driving device 6, the driving currents output from the systems are added by adders 27, 28, and 29, and are then output to the laser-light emitting element 33.

In the erase power system and the read power system of the above-described four power systems, APC (auto power control) is exerted by using feedback control. First, a description will be given of operations of the erase power system and the read power system in which APC is exerted.

An erase DAC 13 converts erase reference data DEref set by the CPU 70 of the control unit 7 from digital to analog, and outputs an erase reference current IEref. The erase reference current IEref represents a target erase power.

An actual erase power of the laser-light emitting element 33 corresponds to an output current Ifm serving as a monitor signal (received-light signal) output from the power detector 34. The output current Ifm is converted into a voltage by a resistor, and is then sampled by a sample-and-hold circuit 12. The sample-and-hold circuit 12 samples the erase power at the timing like a time “te” during generation of erase power in FIG. 2, and outputs an erase sample voltage VEsh to an erase APC (auto-power controller) 19. The erase sample voltage VEsh is also input to an ADC 18 via a switch SW5. After AD conversion, the erase sample voltage VEsh is read as a value indicating an erase light power into the CPU 70.

The erase APC 19 converts the erase reference current IEref into an erase reference voltage VEref, and compares the erase reference voltage VEref with the erase sample voltage VEsh. The erase APC 19 outputs an erase current IEa subjected to APC so that these voltages are equal to each other. For example, when the erase sample voltage VEsh is lower than the erase reference voltage VEref, the output erase current IEa is increased. Conversely, when the erase sample voltage VEsh is higher than the erase reference voltage VEref, the output erase current IEa is decreased.

The current amplifier 24 amplifies the erase current IEa, and outputs an erase current IE. The switch SW2 is ON during an erase period of data recording (writing), that is, during a space writing period (see FIG. 2). As a result, the erase current IE amplified by the current amplifier 24 drives the laser-light emitting element 33 via the adders 28 and 27 only during the erase period.

A voltage input to the current amplifier 24 indicates the intensity of the erase current IEa. The input voltage is input to the ADC 18 via the switch SW5, and is converted from analog to digital. The converted erase current IEa is read into the CPU 70.

Operation of the read power system will now be described.

A read DAC 16 converts read reference data DRref set by the CPU 70 from digital to analog, and outputs a read reference current IRref. The read reference current IRref represents a target read power.

An actual read power of the laser-light emitting element 33 corresponds to the output current Ifm serving as a monitor signal (received-light signal) output from the power detector 34. The output current Ifm is converted into a voltage by the resistor, and is filtered by a low-pass filter 14. A sample-and-hold circuit 15 samples the output from the low-pass filter 14 at the timing like a time “tr” (see FIG. 2) during generation of read power, and outputs a read sample voltage VRsh to a read APC 21. The read sample voltage VRsh corresponds to a read light power.

The read APC 21 converts the read reference current IRref into a read reference voltage VRref, and compares the read reference voltage VRref with the read sample voltage VRsh. The read APC 21 outputs a read current IRa subjected to APC so that the read reference voltage VRref and the read sample voltage VRsh are equal to each other. For example, when the read sample voltage VRsh is lower than the read reference voltage VRref, the read current IRa is increased. Conversely, when the read sample current VRsh is higher than the read reference voltage VEref, the read current IRa is decreased.

The current amplifier 25 amplifies the read current IRa, and outputs a read current IR. The switch SW3 is ON during data reproduction (during reading (see FIG. 2)). As a result, the read current IR amplified by the current amplifier 25 drives the laser-light emitting element 33 via the adders 29, 28, and 27 only during data reproduction.

A voltage input to the current amplifier 25 indicates the intensity of the read current IR. The input voltage is input to the ADC 18 via the switch SW5, and is converted from analog to digital. The converted read current IR is read into the CPU 70. The read sample voltage VRsh corresponding to a read light power is also input to the ADC 18 via the switch SW5, and is read into the CPU 70 after AD conversion.

The low-pass filter 14 and the sample-and-hold circuit 15 in the read power system output an average value VAsh corresponding to an average power Pave (see FIG. 6) of peak power, bottom power, and erase power during data recording. The average value VAsh is also input to the ADC 18 via the switch SW5, and is read into the CPU 70 after AD conversion. The switch SW3 is kept off during writing.

Operations of the peak power system and the bottom power system will now be described. In these two systems, APC is not exerted, but ACC (auto current control) is exerted so as to control the driving current for the laser-light emitting element 33 on the basis of reference data (command driving current) set by the CPU 70 of the control unit 7.

In the peak power system, a peak DAC 11 converts peak reference data DPref set by the CPU 70 from digital to analog, and outputs a peak reference current IPref. The peak reference current IPref corresponds to a target peak power. The current amplifier 23 amplifies the peak reference current IPref, and outputs a peak current IP.

The switch SW1 is ON during a peak power period (see FIG. 2) of data recording (writing). As a result, the peak current IP amplified by the current amplifier 23 drives the laser-light emitting element 33 via the adder 27 only during the peak power period.

As shown in FIG. 2, the period in which the peak power is generated is repeated at considerably short intervals, for example, of about 10 nanoseconds. Correspondingly, the switch SW1 is repeatedly turned on and off at short intervals.

A voltage input to the current amplifier 23 represents the intensity of the peak reference current IPref. The input voltage is input to the ADC 18 via the switch SW5. After AD conversion, the peak reference current IPref is read into the CPU 70.

The bottom power system operates substantially similarly to the peak power system.

A bottom DAC 17 converts bottom reference data DBref set by the CPU 70 from digital to analog, and outputs a bottom reference current IBref. The bottom reference current IBref corresponds to a target bottom power. The current amplifier 26 amplifies the bottom reference current IBref, and outputs a bottom current IB.

The switch SW4 is ON during a bottom power period (see FIG. 2) of data recording (writing). As a result, the bottom current IB amplified by the current amplifier 26 drives the laser-light emitting element 33 via the adders 29, 28, and 27 only during the bottom power period.

The period in which the bottom power is generated is also repeated at considerably short intervals. Correspondingly, the switch SW4 is also turned on and off at short intervals.

The switch SW5 for selectively outputting the driving currents to the ADC 18 and the ADC 18 for outputting the driving current to the CPU 70 after AD conversion constitute a current detecting unit. Further, the peak DAC 11 and the bottom DAC 17 in which the driving current (command driving current) found by the CPU 70 is set, and the current amplifiers 23 and 27 constitute a current driving unit.

### (2) Laser-Power Control Method (First Embodiment)

A detailed description will be given below of a method for controlling the laser power of the laser-light emitting element 33 in the optical disc apparatus 1 and the laser driving device 6 having the above-described configurations.

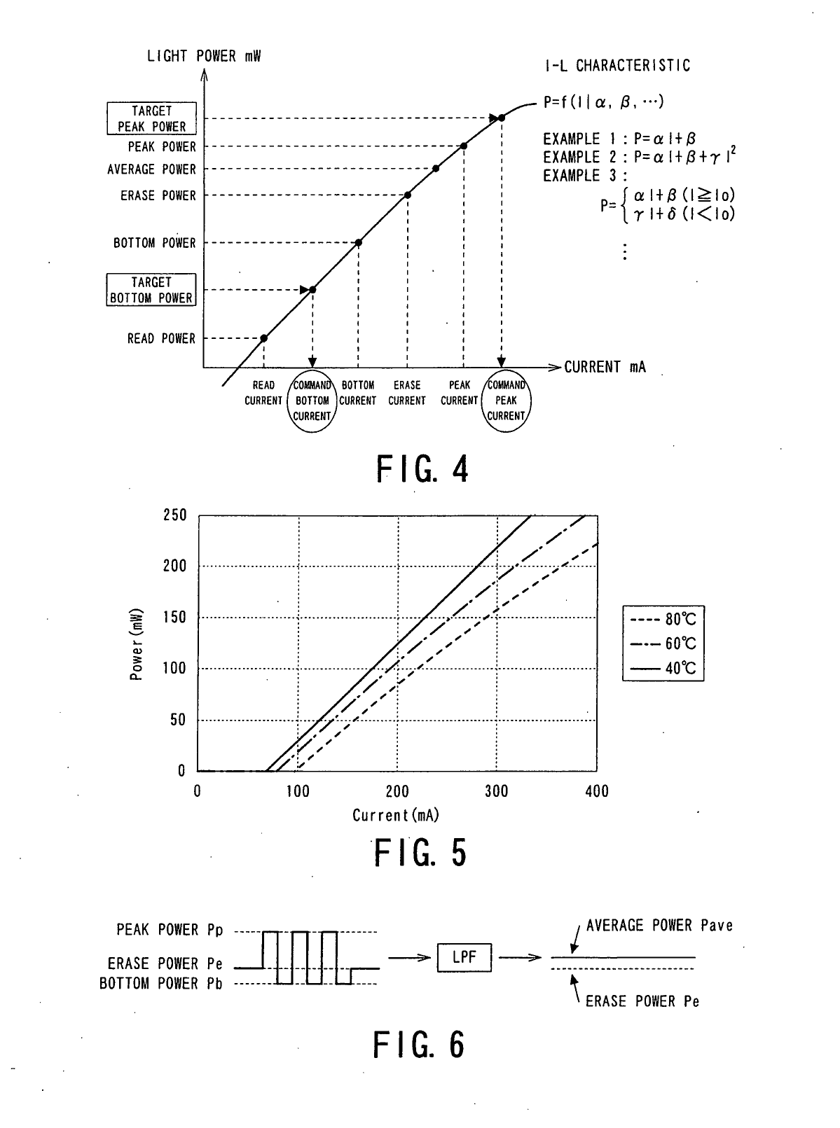

FIG. 4 is a graph showing the relationship between the light power and driving current of the laser-light emitting element 33 (I-L characteristic). The quality of a recording mark formed on the recording layer of the optical disc 100 greatly depends on the accuracy of the peak power of the laser-light emitting element 33. When the quality of a recording mark declines, the quality of a reproduction signal obtained when the recording mark is reproduced also declines. Therefore, it is necessary to precisely control the driving current (peak current) for the laser-light emitting element 33 so that the peak power coincides with a target value.

Conventionally, the light power of the laser-light emitting element 33 is measured with a light-receiving element, such as a photodiode, while changing the intensity of the peak current for generating the peak power, so that a peak current for generating the target peak power is determined. In this measurement of the light power, the current or voltage output from the light-receiving element when the peak power is generated is held in a peak hold circuit, and the held value is read into the CPU after AD conversion.

However, with increases in recording density of data on the optical disc and rotation speed of the disc during recording, the peak hold circuit has been required to achieve a quicker response and a higher accuracy. The use of this peak hold circuit increases the manufacturing cost of the optical disc apparatus. The above also applies to a bottom power that needs high-speed switching at short intervals, as well as the peak power.

Accordingly, in contrast to the related art in which a peak power and a bottom power are sampled at high speed and a peak current and a bottom current are determined on the basis of actually measured powers, in the first embodiment, the I-L characteristic (the characteristic indicating the relationship between the driving current and the light power) is first estimated, and a peak current and a bottom current corresponding to the target peak power and the target bottom power, that is, the optimum peak current and the optimum bottom current are determined on the basis of the I-L characteristic.

The optimum peak current and the optimum bottom current are determined by the control unit 7. More specifically, for example, the CPU 70 of the control unit 7 determines the optimum peak current and the optimum bottom current by executing software for determining the optimum current. The determined optimum peak current and optimum bottom current are respectively set as peak reference data DPref and bottom reference data DBref shown in FIG. 3 in the peak DAC 11 and the bottom DAC 17.

In this method, it is important to precisely estimate the I-L characteristic. Since the I-L characteristic greatly depends on the temperature, as described above, it varies according to the elapsed time from power-on of the optical disc apparatus 1 and the ambient temperature. For this reason, it is necessary to precisely estimate the I-L characteristic on the assumption that the I-L characteristic is variable. A method for estimating the I-L characteristic will be described below.

First, an approximate expression of the I-L characteristic is expressed as the following Expression 1:

P=ƒ(I|α,β, . . . ) (Expression 1)

where the light power P is a function of the driving current I, and the function f includes parameters α, β, . . . . The number of parameters is not limited.

Examples of f(I|α, β, . . . ) are generally given by the following Expressions 2 and 3:

P=ƒ(I|α,β, . . . )=αI+β (Expression 2)

P=ƒ(I|α,β, . . . )=αI+β+γI² (Expression 3)

FIG. 5 is a graph showing actual examples of I-L characteristics. As shown in FIG. 5, the actual I-L characteristic is linear at a relatively low temperature, and can be approximated by Expression 2 serving as a linear expression. In contrast, since the light emitting efficiency decreases at a high temperature, a higher accuracy is ensured by performing approximation with Expression 3 serving as a quadratic expression. While Expressions 2 and 3 involve a power function, the shape of the function is not limited thereto. A plurality of functions may be combined as in the following example. In the following example, I₁, I₂, . . . represent, for example, intersections of straight lines.

$$\begin{matrix}P = f ( I \vert α , β , … ) \\ = \{ \begin{matrix}{f}_{1} ( I \vert {α}_{1} , {β}_{1} , … ) ( I \leq {I}_{1} ) \\ {f}_{2} ( I \vert {α}_{2} , {β}_{2} , … ) ( {I}_{1} < I \leq {I}_{2} )\end{matrix} \\ = \{ \begin{matrix}{α}_{1} I + {β}_{1} ( I \leq {I}_{1} ) \\ {α}_{2} I + {β}_{2} ( {I}_{1} < I )\end{matrix}\end{matrix} \qquad ( Expression 4 )$$

When the I-L characteristic f(I|α, β, . . . ) is found, a command driving current for achieving the target power can be calculated by using an inverse function f⁻¹(P|α, β, . . . ) thereof.

For example, inverse functions f⁻¹(P|α, β, . . . ) of Expressions 2 and 3 are expressed as follows. The rightmost term in Expression 6 represents an approximate expression when |γ|<1, γ<0, β<0, and P>0.

$$\begin{matrix}I = {f}^{- 1} ( P \vert α , β , … ) = \frac{P - β}{α} & ( Expression 5 ) \\ \begin{matrix}I = {f}^{- 1} ( P \vert α , β , … ) \\ = \frac{- α + \sqrt{{α}^{2} - 4 γ ( β - P )}}{2 γ} \\ \approx \frac{P - β}{α} - \frac{{γ ( β - P )}^{2}}{{α}^{3}}\end{matrix} & ( Expression 6 )\end{matrix}$$

The relationship between the erase power and the average power will now be described with reference to FIG. 6. The erase APC 119 controls the erase power by feedback control so that the erase power sampled in the space period by the sample-and-hold circuit 12 is equal to the target erase power. A driving current for the laser-light emitting element 33 that generates light with the target erase power under APC is acquired via the AD converter 18.

In contrast, the average power is acquired via the AD converter 18 by passing the output from the power detector 34 (front monitor) through the low-pass filter 14 so as to remove a high-frequency component, and sampling the output by the sample-and-hold circuit 15. As shown in FIGS. 2 and 6, the average power and the erase power do not include changes at short intervals of, for example, several tens of nanoseconds. Therefore, the power detector 34 and the sample-and-hold circuits 12 and 15 for measuring the powers are not required to have high responsiveness.

A specific example of a laser-power control method according to the first embodiment will be described.

As described above, in the first embodiment, the I-L characteristic of the laser-light emitting element 33 is estimated from the following measured current and light power that can be obtained without using the expensive, quick-response and precise peak hold circuit and the power detector 34 (front monitor) having a wide band characteristic.

(a) a measured erase power in writing and a measured erase current corresponding thereto

(b) a measured average power in writing, and a measured erase current, a measured peak current, and a measured bottom current corresponding thereto

(c) a measured read power in reading and a measured current corresponding thereto

The I-L characteristic can also be estimated from the above (a) to (c). Not all of the above (a) to (c), however, are required. Herein, a method for estimating the I-L characteristic from the above (a) and (b) will be described as a typical example.

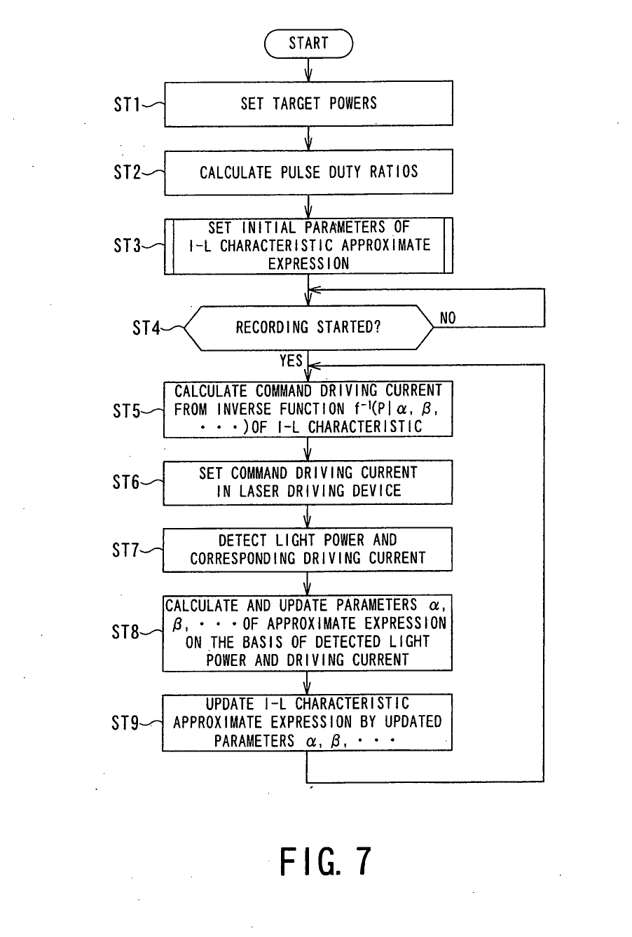

FIG. 7 is a flowchart showing an example of the laser-power control method (first embodiment) according to the present invention. Steps in FIG. 7 are performed under control of the CPU 70.

First, in Step ST1, target powers are set. More specifically, the CPU 70 loads a target peak power Pp, a target erase power Pe, and a target bottom powers Pb in an appropriate memory such as the RAM 72. Further, the CPU 70 sets peak reference data DPref, erase reference data DEref, and bottom reference data DBref corresponding to the target peak power Pp, the target erase power Pe, and the target bottom power Pb, respectively, in the peak DAC 11, the erase DAC 13, and the bottom DAC 17.

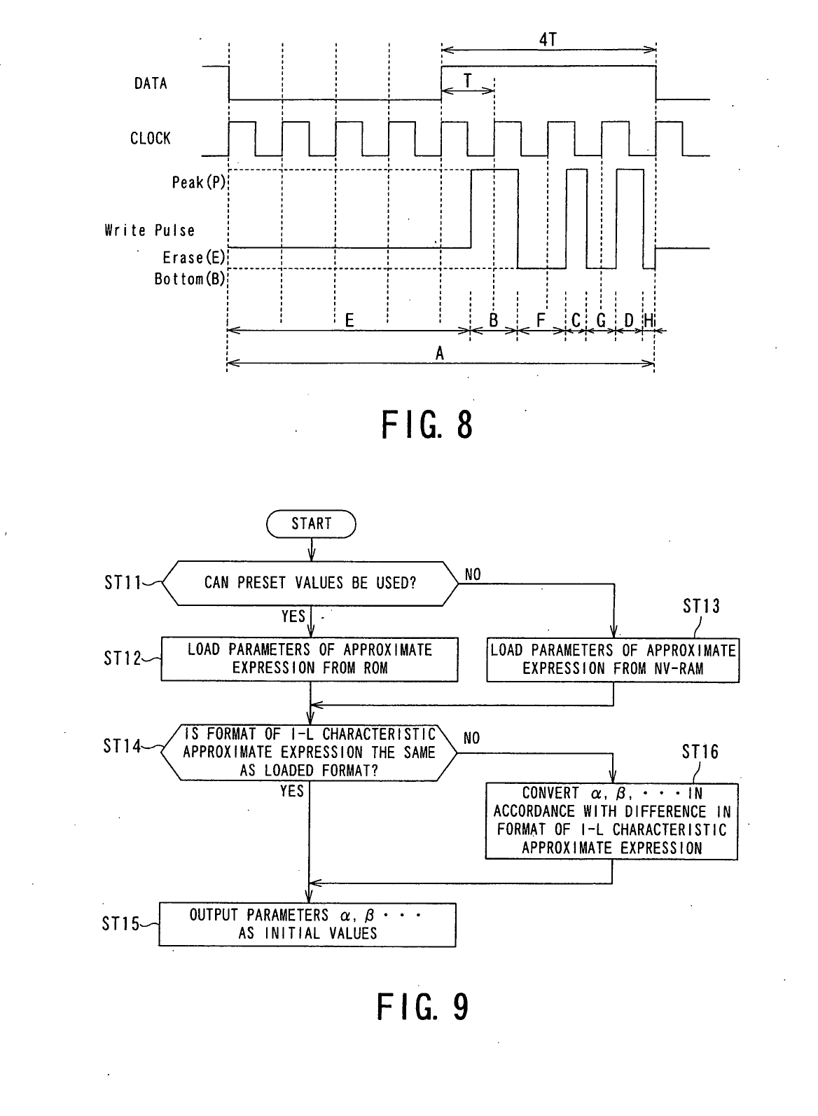

In Step ST2, the pulse duty ratios are calculated from the current write strategy. For example, when a write strategy shown in FIG. 8 is used, the pulse duty ratios are calculated as follows:

$$\begin{matrix}dp = \frac{B + C + D}{A} & ( Expression 7 ) \\ de = \frac{E}{A} & ( Expression 8 ) \\ db = \frac{F + G + H}{A} & ( Expression 9 )\end{matrix}$$

Herein, dp, de, and db respectively represent the duty ratios of the peak power, the erase power, and the bottom power, and dp+de+db=1. A represents the data cycle, B, C, and D represent the peak widths in one data cycle, E represents the erase width, and H represents the bottom width. When the influences of the space length and the mark length are considered, the above values may be averaged with weighting on the basis of the frequency of appearance of the spaces and marks.

In Step S3, initial values of parameters used in the I-L characteristic approximate expression are set. FIG. 9 is a flowchart showing details of Step ST3.

First, in Step ST11, it is determined whether preset values can be used. When the present values can be used, preset values stored in the ROM 73 are loaded (Step ST12). In contrast, when it is determined that the preset values cannot be used, previous parameters stored in the nonvolatile memory NV-RAM 74 are loaded (Step ST13). The previous parameters refer to parameters finally stored in the previous operation of the optical disc apparatus 1 for writing on the optical disc 100 or another optical disc.

For example, when the parameters used in the previous writing operation do not remain in the NV-RAM 74, it is, of course, determined in Step ST11 that the preset values cannot be used. Further, when the laser-light emitting element 33 was used for a short period at the room temperature, it can be considered that the I-L characteristic did not change greatly. Therefore, it is determined that parameters preset at, for example, shipment and stored in the ROM 73 can be used.

In Step ST14, it is determined whether the format of the I-L characteristic approximate expression is the same as the format of an approximate expression corresponding to the loaded parameters. For example, when the loaded parameters correspond to a linear expression (Expression 1), but it is determined that a quadratic expression (Expression 3) is better as the approximate expression because the current temperature is high (No in Step ST14), Step ST16 is performed to convert the parameters in accordance with the difference of the format of the approximate expression.

For example, when a quadratic approximate expression is to be used and the loaded parameters correspond to a linear expression, the following conversions are performed. New parameters obtained by conversion are set as initial values, and the next step is performed (Step ST15):

α←αload (Expression 10)

β←βload (Expression 11)

γ←0 (Expression 12)

where α, β, and γ in the left side represent parameters corresponding to the quadratic expression, and αload and βload in the right side represent parameters stored corresponding to the linear expression.

In contrast, when it is determined that the format of the I-L characteristic approximate expression is the same as the format of the approximate expression corresponding to the loaded parameters (Yes in Step ST14), the loaded parameters are set as initial values, and the next step is performed (Step ST15).

Referring again to FIG. 7, a trigger (command) for starting recording is waited for in Step ST4. When recording is started, Step ST5 is performed.

In Step ST5, command driving currents Ip and Ib for causing the laser-light emitting element 33 to emit light with the target peak power Pp and the target bottom power Pb are respectively calculated from an inverse function f⁻¹(I|α, β, . . . ) of the latest I-L characteristic approximate expression by the following expressions:

Ip=ƒ⁻¹(Pp|α,β, . . . ) (Expression 13)

Ib=ƒ⁻¹(Pb|α,β, . . . ) (Expression 14)

While the I-L characteristic approximate expression itself is sequentially updated by updating the parameters thereof in the flowchart shown in FIG. 7, the command driving currents Ip and Ib are calculated by the latest I-L characteristic approximate expression in Step ST5. At the first recording time, the initial parameters set in Step ST3 are used.

In the next Step ST6, the command driving currents Ip and Ib calculated in Step ST5 are respectively set as peak reference data DPref and bottom reference data DBref in the peak DAC 11 and the bottom DAC 17 of the laser driving device 6.

In this stage, light with a peak power and a bottom power is output from the laser-light emitting element 33 on the basis of the set command driving currents Ip and Ib, and recording on the optical disc 100 is started. Independently of the above-described process, the erase power is subjected to APC.

When recording is started, the light power and the corresponding driving current are detected (Step ST7). More specifically, an erase power (a voltage VEsh output from the sample-and-hold circuit 12 in FIG. 3) and an erase current (a voltage at an output terminal of the erase APC 19) are acquired as digital signals from the AD converter 18. Further, a voltage (VAsh in FIG. 3) output from the sample-and-hold circuit 15 in recording is acquired as an average power Pave from the ADC 18. A bottom current (a voltage IBref output from the bottom DAC 17) and a peak current (a voltage IPref output from the peak DAC 11) are also acquired. The average power Pave has the following relationship with the erase power Pe, the peak power Pp, and the bottom power Pb:

Pave=dePe+dpPp+dbPb (Expression 15)

In Step ST8, the parameters of the I-L characteristic approximate expression are calculated and updated by using the erase power Pe and the corresponding erase current Ie, the bottom current Ib, the erase current Ie, and the peak current Ip corresponding to the average power Pave, and the pulse duty ratios de, dp, and db calculated in Step ST2. More specifically, calculation and updating are performed as follows:

First, an estimated erase power Pe_{E}, an estimated peak power Pp_{E}, and an estimated bottom power Pb_{E} are calculated from the current I-L characteristic approximate expression f(I|α, β, . . . ) as follows:

Pe_{E}=ƒ(Ie|α,β, . . . ) (Expression 16)

Pp_{E}=ƒ(Ip|α,β, . . . ) (Expression 17)

Pb_{E}=ƒ(Ib|α,β, . . . ) (Expression 18)

In the above-described expressions, Ie, Ip, and Ib respectively represent the erase current, peak current, and bottom current detected in Step ST7.

An estimated average power Pave_{E} has the following relationship with the estimated erase power Pe_{E}, the estimated peak power Pp_{E}, and the bottom power Pb_{E}, similarly to Expression 15:

Pave_{E}=dePe_{E}+dpPp_{E}+Pb_{E} (Expression 19)

For example, an estimation error E given by the following expression is defined as the standard for coincidence between the estimated value and the measured value:

$$\begin{matrix}E = \frac{1}{2} ( {e}_{ave}^{2} + {e}_{e}^{2} ) \\ = \frac{1}{2} ( {( {Pave}_{E} - Pave )}^{2} + {( {Pe}_{E} - Pe )}^{2} )\end{matrix} \qquad ( Expression 20 )$$

For example, the parameters α, β, . . . that minimize the estimation error E can be estimated by a steepest gradient method. In the steepest gradient method, the parameters α, β, . . . are updated so that the estimation error E sequentially decreases. The update amounts δα, δβ, . . . of the parameters (differences from the current parameter values) can be calculated as follows:

$$\begin{matrix}δ α = \frac{\partial E}{\partial α} & ( Expression 21 ) \\ δβ = \frac{\partial E}{\partial B} & ( Expression 22 )\end{matrix}$$

When a linear expression (Expression 2) is used as the I-L characteristic approximate expression, δα and δβ described above can be calculated as follows:

$$\begin{matrix}δα = {e}_{ave} \frac{\partial {Pave}_{E}}{\partial α} + {e}_{e} \frac{\partial {Pe}_{E}}{\partial α} = {e}_{ave} ( {I}_{ave} ) + {e}_{e} ( {I}_{e} ) & ( Expression 23 ) \\ δβ = {e}_{ave} \frac{\partial {Pave}_{E}}{\partial β} + {e}_{e} \frac{\partial {Pe}_{E}}{\partial β} = {e}_{ave} + {e}_{e} & ( Expression 24 )\end{matrix}$$

where Iₐᵥₑ represents the average current. The average current Iₐᵥₑ is given by the following expression:

Iₐᵥₑ=dpIp+deIe+dbIb (Expression 25)

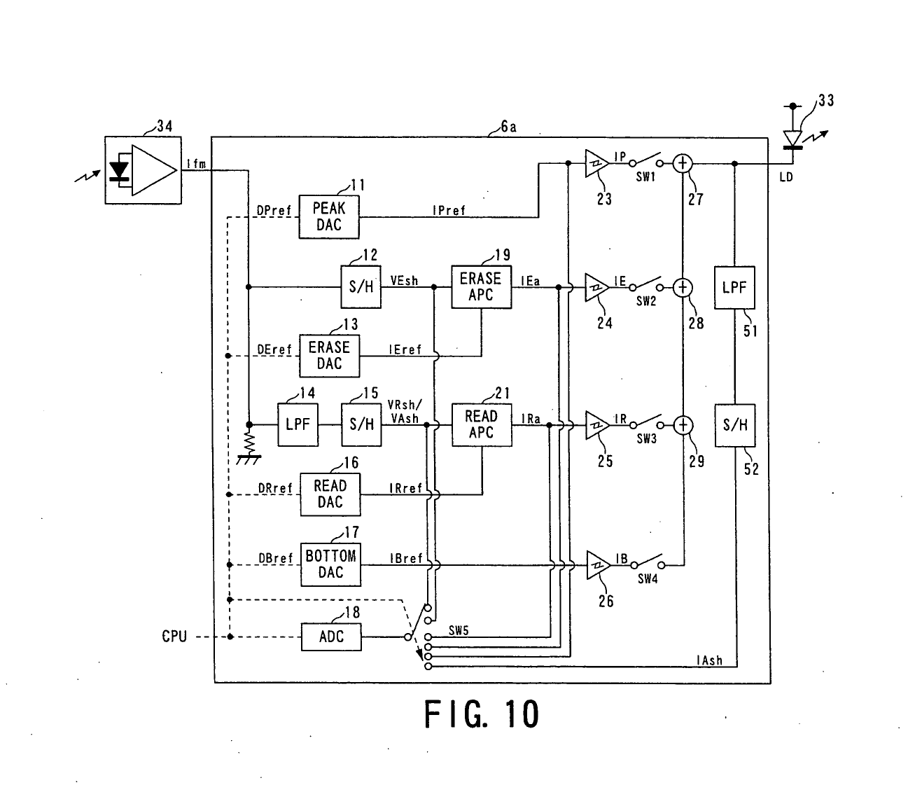

Instead of the above calculation, the average current Iₐᵥₑ may be found using hardware of the laser driving device 6. FIG. 10 shows a configuration of the laser driving device 6 adopted in a modification in which the average current Iₐᵥₑ is found by the hardware. In this modification, a low-pass filter LPF 51 is provided on the most downstream side of the laser driving device 6 so as to smoothen the driving current, and an average current Iₐᵥₑ output from the LPF 51 is sampled by a sample-and-hold circuit S/H 52, and is read into a CPU 70 via a switch SW5 and an ADC 18.

When a quadratic expression (Expression 3) is used as the I-L characteristic approximate expression, the update amounts δα, δβ, and δγ of α, β, and γ are given as follows:

$$\begin{matrix}δα = {e}_{ave} \frac{\partial {Pave}_{E}}{\partial α} + {e}_{e} \frac{\partial {Pe}_{E}}{\partial α} = {e}_{ave} ( {I}_{ave} ) + {e}_{e} ( {I}_{e} ) & ( Expression 26 ) \\ δβ = {e}_{ave} \frac{\partial {Pave}_{E}}{\partial β} + {e}_{e} \frac{\partial {Pe}_{E}}{\partial β} = {e}_{ave} + {e}_{e} & ( Expression 27 ) \\ \begin{matrix}δγ = {e}_{ave} \frac{\partial {Pave}_{E}}{\partial γ} + {e}_{e} \frac{\partial {Pe}_{E}}{\partial γ} \\ = {e}_{ave} ( {dpIp}^{2} + {deIe}^{2} + {dbIb}^{2} ) + {e}_{e} ( {Ie}^{2} )\end{matrix} & ( Expression 28 )\end{matrix}$$

The above-described Expressions 23, 24 and 26 to 28 do not include division processes, and this reduces the calculation cost.

The parameters α, β, . . . are updated on the basis of the update amounts δα and δβ (or δα, δβ, and δγ) as follows:

α←α−k×δα (Expression 29)

β←β−k×δβ (Expression 30)

where k is the parameter for adjusting the update amount. The parameter k may be a fixed value, a value that depends on the number of update operations, or a value that depends on the estimation error E.

As described above, the I-L characteristic approximate expression is updated by substituting the parameters α, β, . . . , which are calculated and updated in Step ST8, into the expression in Step ST9. Subsequently, the procedure returns to Step ST5, the light power is controlled by periodically executing the loop.

In the laser-power control method according to the first embodiment, even when the I-L characteristic varies with, for example, the temperature, or even when the I-L characteristic is not linear but nonlinear, it can be estimated while following the variation of the I-L characteristic and sequentially increasing the accuracy.

When recording on the optical disc 100 is completed, the parameters α, β, . . . and the format information about the approximate expression (f(I|α, β, . . . ) (information about determination whether the approximate expression is a linear expression or a quadratic expression) are stored in the nonvolatile memory NV-RAM 92 or the like. Not only the latest data but also historical information may be stored. In order to change the write strategy, the procedure shown in FIG. 7 is performed again from the beginning.

In the configuration of the optical disc apparatus 1, the approximate-expression updating unit corresponds to the means for performing the above-described Steps ST 8 and 9, and the command-driving-current calculating unit corresponds to the means for performing the above-described Step ST5.

### (3) Laser-Power Control Methods (Second to Sixth Embodiments)

Various embodiments other than the above-described embodiment can be adopted.

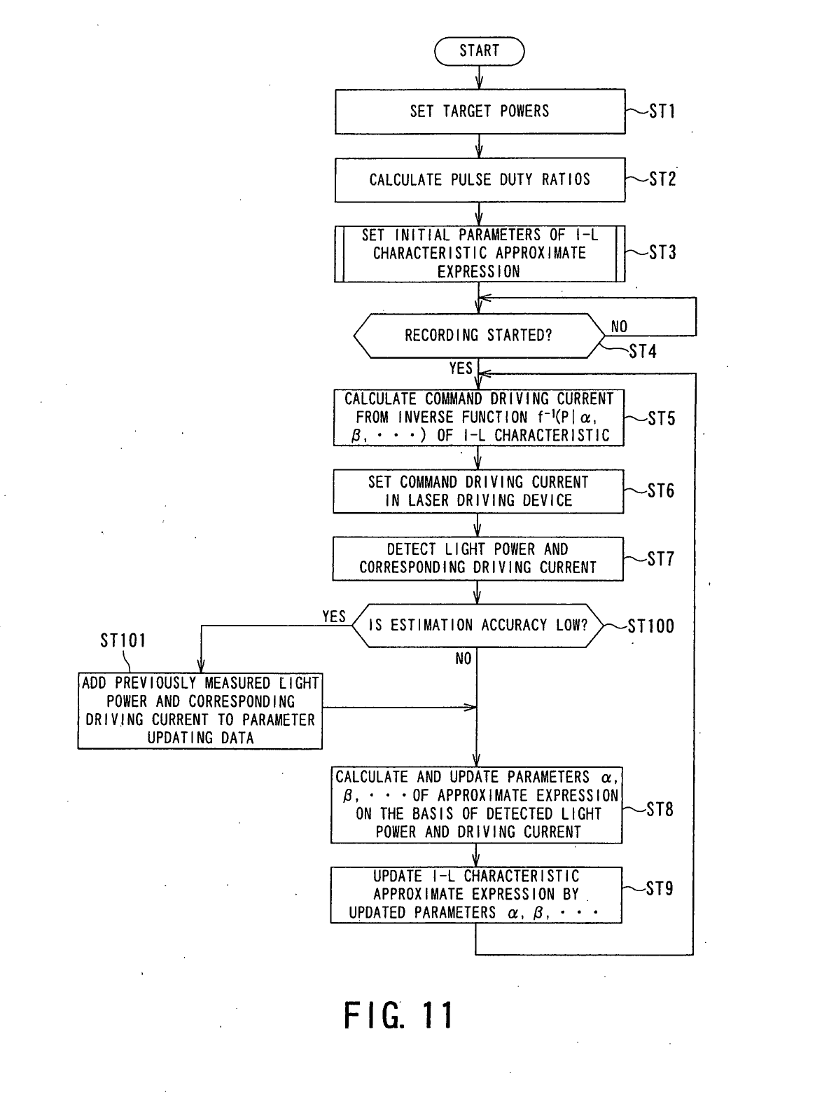

FIG. 11 is a flowchart showing a laser-power control method according to a second embodiment. The same steps as those in the first embodiment (FIG. 7) are denoted by the same step numbers.

In the laser-power control method of the second embodiment, it is determined in Step ST100 whether the estimation accuracy is low. When the estimation accuracy is low, Step ST101 is performed to add the previously measured light power and the corresponding driving current to parameter updating data.

It is conceivable that the estimation accuracy is decreased because of much measurement noise or the like. For example, the decrease in estimation accuracy can be checked on the basis of the update amounts δα and δβ.

In this case, all or some of the previously measured erase power and the corresponding measured erase current, and the measured average power and the corresponding erase current, peak current, and bottom current may be loaded and added to the updating data.

Similarly, when the estimation accuracy decreases, for example, because the average power is close to the erase power, the previously measured read power and the corresponding measured read current may be added. It is preferable that these additional data be obtained under the same ambient condition (e.g., temperature). For example, an average power, an erase power, and a read power can be obtained under the same condition by inserting a read sequence at low frequency in a write sequence.

In general, estimation can become robuster as the number of update data increases. If the number of update data is less than the number of parameters, it is impossible to uniquely determine the parameters. In order to avoid this problem, it is better that the number of update data is large.

In order to add the read power and the read current to the updating data, an estimated read power Pr_{E} is calculated from a measured read current Ir by the following expression:

Pr_{E}=ƒ(Ir|α,β, . . . ) (Expression 31)

Subsequently, the estimation error E is redefined by the following expression:

$$E = \frac{1}{2} {( {Pave}_{E} - Pave )}^{2} + {( {Pe}_{E} - Pe )}^{2} + {( {Pr}_{E} - Pr )}^{2} ) \qquad ( Expression 32 )$$

The update amounts δα, δβ, . . . can be given by Expressions 21 and 22 described above.

When past data is added, the estimation error is redefined by adding a term of square error and calculation is performed by the update expression, in a manner similar to the above.

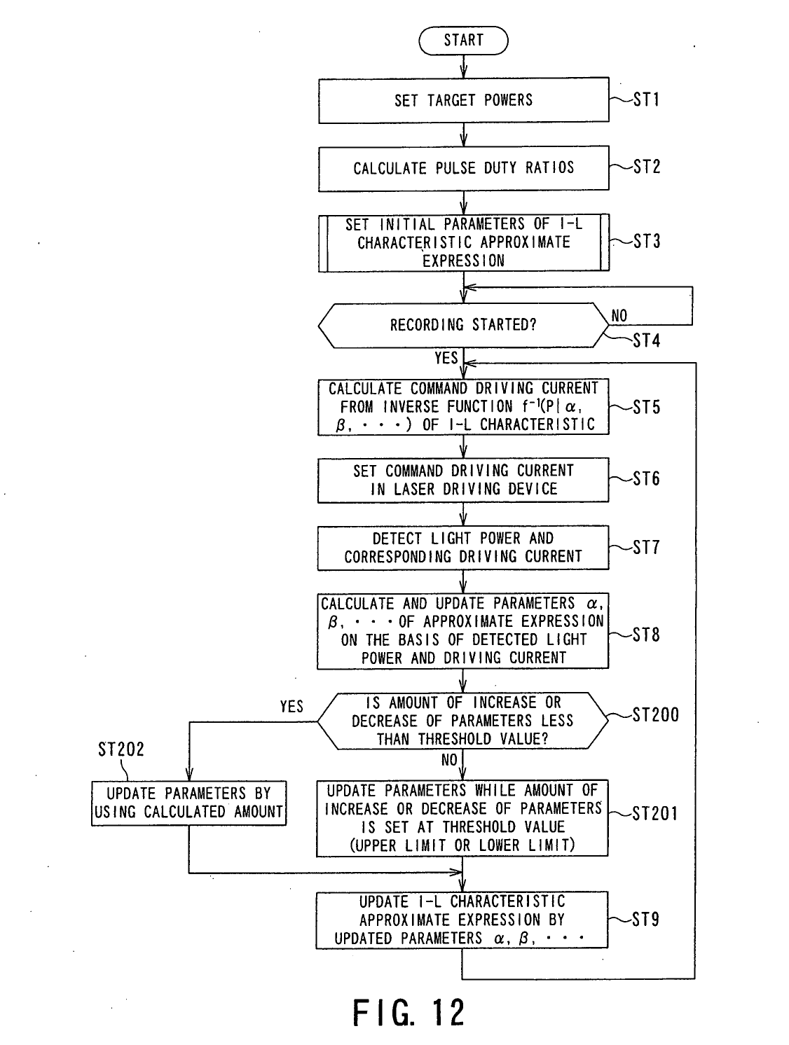

FIG. 12 is a flowchart showing a laser-power control method according to a third embodiment. In the laser-power control method of the third embodiment, when the update amount of a parameter exceeds a predetermined threshold value, it is limited. While the update amount generally increases when parameter updating is started or when the ambient temperature greatly changes, stability of convergence is increased by limiting the update amount in this case.

More specifically, it is determined in Step ST200 whether the amount of increase or decrease of the parameter is less than or equal to a predetermined threshold value. When the amount exceeds the threshold value, the update amount (amount of increase or decrease) of the parameter is set at the threshold value as a limit value, and the parameter is updated by the value (Step ST201). When the amount of increase or decrease of the parameter is less than or equal to the predetermined threshold value, the parameter is updated by the calculated update amount (Step ST202).

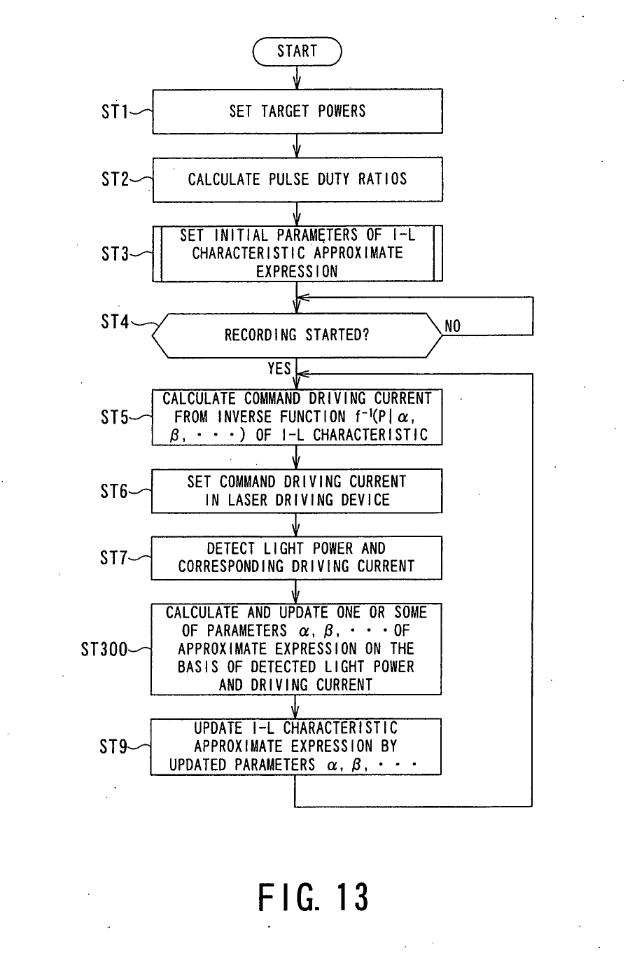

FIG. 13 is a flowchart showing a laser-power control method according to a fourth embodiment. In the laser-power control method of the fourth embodiment, all parameters are not updated, but one or some of the parameters are updated, as in Step ST300. This reduces the calculation cost. For example, this method is applied when the inclination of the I-L characteristic is known and only the offset is to be adjusted. In this case, for example, of the parameters α and β (or α, β, and γ), only β corresponding to the offset is updated.

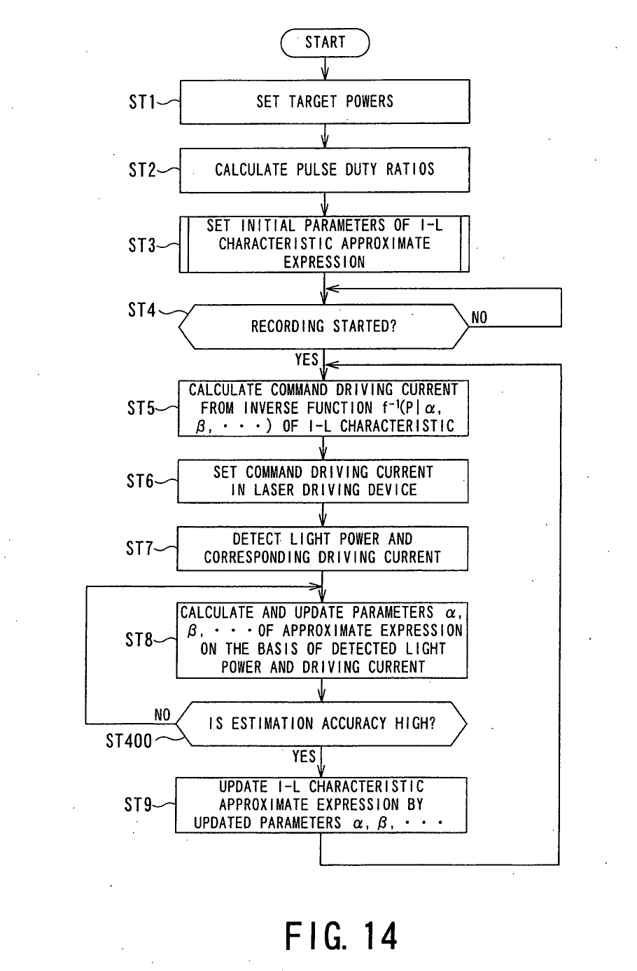

FIG. 14 is a flowchart showing a laser-power control method according to a fifth embodiment. In the laser-power control methods according to the first to fourth embodiments, after the parameters α, β, . . . are updated once on the basis of the detected light power and driving current, they are immediately substituted into the I-L characteristic approximate expression so as to update the I-L characteristic approximate expression.

In contrast, in the laser-power control method of the fifth embodiment, the parameters α, β, . . . are updated a plurality of times on the basis of the detected light power and driving current.

This method is effective when the estimation accuracy of the I-L characteristic approximate expression does not seem to be so high, for example, immediately after updating of the I-L characteristic approximate expression is started, or when the ambient temperature greatly changes.

In Step ST400 in FIG. 14, the estimation accuracy of the I-L characteristic approximate expression is judged. When it is determined that the estimation accuracy is judged low (No in Step ST400), Step ST8 is performed again so as to repeat calculation and updating of the parameters α, β, . . . a plurality of times.

The method for judging the estimation accuracy is not particularly limited. For example, the estimation accuracy is judged on the basis of the update amounts δα, δβ, . . . or the number of operations of executing a loop (a loop returning from Step ST9 to Step ST5 or a loop returning from Step ST400 to Step ST8).

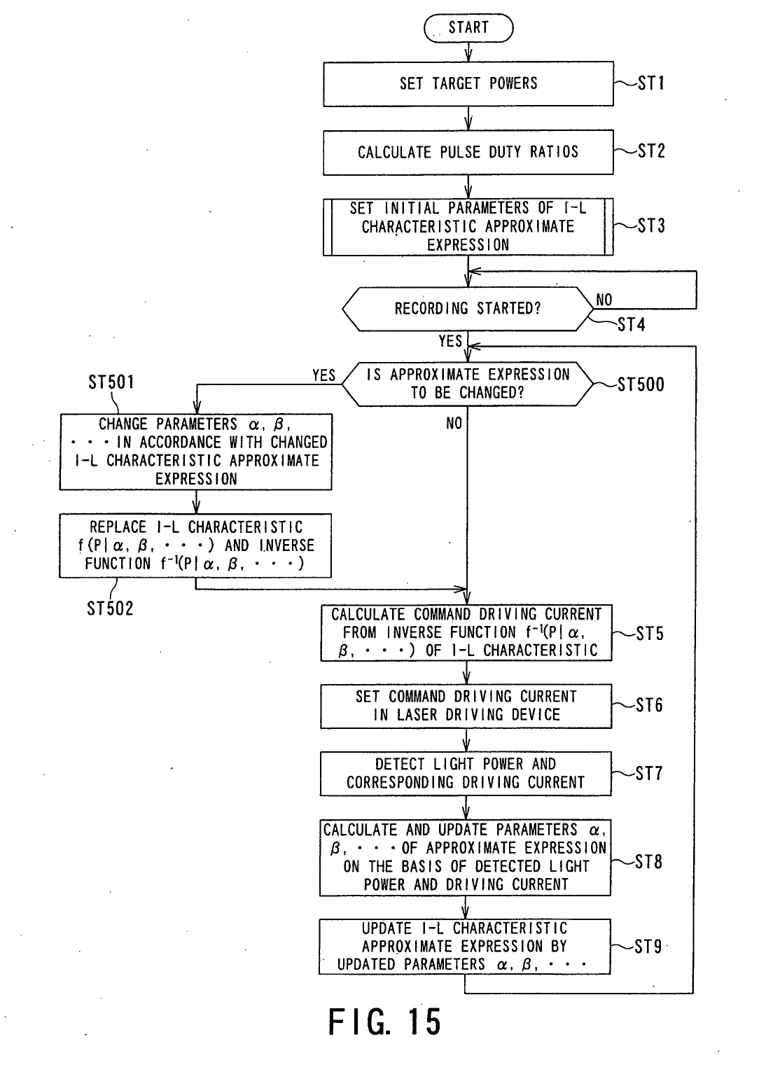

FIG. 15 is a flowchart showing a laser-power control method according to a sixth embodiment. In the laser-power control method of the sixth embodiment, the format of the I-L characteristic approximate expression can be changed during an operation of updating the I-L characteristic approximate expression.

For example, a linear approximate expression (Expression 2) is used at a low temperature, and a quadratic approximate expression (Expression 3) is used at a high temperature. Since the approximate expression closer to the actual I-L characteristic that varies in accordance with the temperature or the like is selected in this method, the estimation accuracy of the I-L characteristic is increased.

More specifically, it is determined on the basis of information about the temperature or the like in Step ST500 in FIG. 15 whether to change the approximate expression. When the change is necessary, the parameters α, β, . . . are replaced correspondingly to the format of a changed approximate expression in Step ST501. Further, in Step ST502, the I-L characteristic approximate expression and an inverse function thereof are replaced with functions to which the present functions are to be changed. Subsequent steps are performed similarly to the above-described embodiments.

### (4) Laser-Power Control Methods (Other Embodiments)

In the first to sixth embodiments, the update frequency for the I-L characteristic approximate expression may be changeable. For example, updating may be frequently performed when the temperature of the laser-light emitting element 33 greatly changes or immediately after updating of the I-L characteristic approximate expression starts. Conversely, when the temperature is stabilized or when the number of times of updating reaches a sufficient number, the update frequency may be decreased.

While the steepest gradient method is used as an example of a method for updating the parameters of the I-L characteristic approximate expression in the laser-power control methods of the first to sixth embodiments, it may be replaced, for example, with a Newton's method, which increases the speed of convergence, when the CPU 70 has high calculation performance.

When the Newton's method is used, the update amounts δα, δβ, . . . of the parameters can be calculated as follows:

$$( \begin{matrix}δα \\ δβ \\ ⋮\end{matrix} ) = {H}^{- 1} g = {( \begin{matrix}\frac{{\partial }^{2} E}{{\partial }^{2} α} & \frac{{\partial }^{2} E}{\partial α \partial β} & … \\ \frac{{\partial }^{2} E}{\partial α \partial β} & \frac{{\partial }^{2} E}{{\partial }^{2} B} & … \\ ⋮ & ⋮ & ⋰\end{matrix} )}^{- 1} ( \begin{matrix}\frac{\partial E}{\partial α} \\ \frac{\partial E}{\partial β} \\ ⋮\end{matrix} ) \qquad ( Expression 33 )$$

When the update amounts δα, δβ, . . . of the parameters are calculated by the Newton's method, the coefficient k in the update expressions (Expressions 29 and 30) for the parameters α, β, . . . is generally set at 1.

Instead of the Newton's method, for example, a quasi-Newton's method can be used in which H⁻¹ in Expression 33 is not directly calculated.

The method for updating the parameters α, β, . . . may be appropriately changed during the procedure. For example, the Newton's method may be used immediately after the initial parameters are loaded, and, after the update amounts become sufficiently small, the Newton's method may be switched to a steepest descent method.

It is known that, when the I-L characteristic approximate expression is expressed by a linear combination of the parameters and the variable, as in Expressions 2 and 3, the parameters that minimize the square error E defined in Expressions 20 and 32 can be obtained by one calculating operation without using the serial update method such as the steepest gradient method or the Newton's method (e.g., see Hitoshi Arai, Senkei Daisu Kiso to Ouyou, p. 285).

For example, when a quadratic expression (Expression 3) is used as the I-L characteristic approximate expression and when Expression 32 is used as an expression for defining the estimation error E, the parameters that minimize the estimation error E can be obtained by the following expressions:

$$( \begin{matrix}γ \\ α \\ β\end{matrix} ) = {A}^{\#} ( \begin{matrix}{P}_{e} \\ {P}_{ave} \\ {P}_{r}\end{matrix} ) = {( {A}^{t} A )}^{- 1} {A}^{t} ( \begin{matrix}{P}_{e} \\ {P}_{ave} \\ {P}_{r}\end{matrix} ) \qquad ( Expression 34 )$$

where A represents the following matrix. In this case, the following expression is given:

A^{#}=A⁻¹ (Expression 35)

$$A = ( \begin{matrix}{I}_{e}^{2} & {I}_{e} & I \\ {I}_{ave}^{2} & {I}_{ave} & I \\ {I}_{r}^{2} & {I}_{r} & I\end{matrix} ) \qquad ( Expression 36 )$$

For example, when the calculating performance of the CPU 70 is high, the parameters may be updated by the above-described expression only at the first time, and may follow subsequent small changes in the I-L characteristic by a serial update method.

While the measured currents (erase current Ie, peak current Ip, and bottom current Ib) are used when calculating the estimated erase power Pe_{E}, the estimated peak power Pp_{E}, and the estimated bottom power Pb_{E} in Expressions 16 to 18, one or some of the measured currents may serve as a command current value. For example, while the peak current Ip and the bottom current Ib may be obtained from the IPref and IBref shown in FIG. 3 via the ADC 18, these values are substantially identical to the values set in Step ST1 in FIG. 7. Therefore, the measured values may be replaced with these set values.

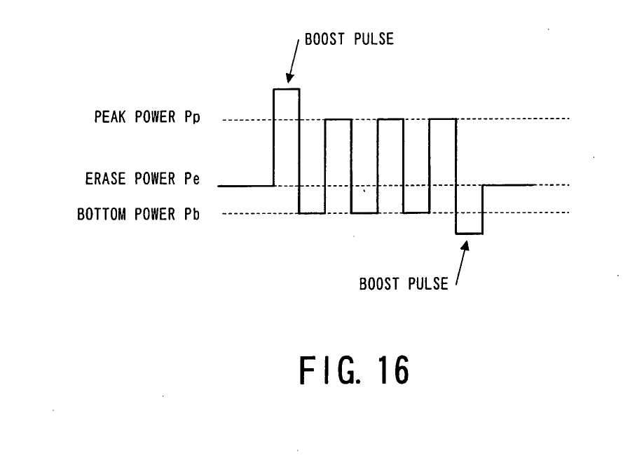

Depending on the type of the write strategy for forming recording marks, in addition to the three levels of waveforms, the peak power Pp, the erase power Pe, and the bottom power Pb, a waveform called a boost pulse is sometimes added to each of the front and rear edges of a sub-pulse train, as illustrated in FIG. 16.

In this case, the I-L characteristic approximate expression can also be estimated by measuring or calculating an average power Pₐᵥₑ and an average current Iₐᵥₑ including the boost pulses, similarly to the above-described procedure. Therefore, when a target boost pulse is given, a command current for achieving the target boost pulse can be calculated by the I-L characteristic approximate expression.

According to the above-described embodiments, even when the I-L characteristic is changed by the temperature or even when the I-L characteristic is not linear, but is non-linear, it can be estimated while following the changes and sequentially increasing the accuracy. As a result, the laser-light emitting element 33 can be controlled to constantly emit light with the required power without using a peak hold circuit and a power detector (front monitor) that are expensive and are required to achieve a high speed, a high accuracy, and a wide band.

The present invention is not limited to the above-described embodiments, and can be carried out by modifying the components within the scope of the invention. The present invention also can be carried out by appropriately combining a plurality of components in each embodiment. For example, some of the components described in the embodiment may be omitted. Further, the components in different embodiments may be combined appropriately.

What is claimed is:

1. A laser-power control method comprising:
detecting a power of a laser light emitted from a laser-light emitting element onto an optical disc;
detecting a driving current driving the laser-light emitting element;
updating an approximate expression on the basis of the detected laser light power and the detected driving current to increase accuracy, the approximate expression indicating a driving-current to light-power characteristic of the laser-light emitting element;
calculating a command driving current corresponding to a target light power using the updated approximate expression; and
driving the laser-light emitting element on the basis of the calculated command driving current so that the laser-light emitting element outputs the target light power.

2. The laser-power control method according to claim 1, wherein approximate-expression updating comprises updating a parameter of the approximate expression so as to decrease a first error defined by a difference between the detected light power and an estimated light power obtained by applying the detected driving current to the approximate expression.

3. The laser-power control method according to claim 2, wherein approximate-expression updating comprises limiting an update amount of the parameter.

4. The laser-power control method according to claim 2, wherein the approximate expression comprises a plurality of parameters, and approximate-expression updating comprises updating at least one of the parameters.

5. The laser-power control method according to claim 2, wherein approximate-expression updating comprises updating the parameter of the approximate expression a plurality of times.

6. The laser-power control method according to claim 2, wherein approximate-expression updating comprises updating the approximate expression by changing the format of the approximate expression.

7. The laser-power control method according to claim 2, wherein approximate-expression updating comprises adding a second error defined by a difference between a previously estimated light power and a previously detected light power to the first error, and further comprises updating the parameter of the approximate expression so as to decrease the first and second errors.

8. The laser-power control method according to claim 1, wherein approximate-expression updating comprises changing a frequency of updates of the approximate expression on the basis of at least one of an ambient temperature and an elapsed time from the start of recording.

9. The laser-power control method according to claim 1,
wherein the laser-light emitting element is configured to switch between a plurality of light powers,
wherein power detecting comprises detecting an average light power obtained by smoothening the light powers, and
wherein approximate-expression updating comprises updating the approximate expression using the average light power.

10. The laser-power control method according to claim 1,
wherein the laser-light emitting element is configured to switch among a plurality of light powers,
wherein driving-current detecting comprises detecting an average driving current obtained by smoothening a plurality of driving currents corresponding to the light powers, and
wherein approximate-expression updating comprises updating the approximate expression by using the average driving current.

11. An optical disc apparatus comprising:
a laser-light emitting element configured to emit laser light onto an optical disc;
a power detecting unit configured to detect a power of the laser light emitted from the laser-light emitting element;
a driving-current detecting unit configured to detect a driving current of the laser-light emitting element;
an approximate-expression updating unit configured to update an approximate expression on the basis of the detected light power and the detected driving current to increase accuracy, the approximate expression indicating a driving-current to light-power characteristic of the laser-light emitting element;
a command-driving-current calculating unit configured to calculate a command driving current corresponding to a target light power using the updated approximate expression; and
a current driving unit configured to drive the laser-light emitting element on the basis of the calculated command driving current so that the laser-light emitting element outputs the target light power.

12. The optical disc apparatus according to claim 11, wherein the approximate-expression updating unit is configured to update the approximate expression by updating a parameter of the approximate expression so as to decrease an error defined by a difference between the detected light power and an estimated light power obtained by applying the detected driving current to the approximate expression.

13. The optical disc apparatus according to claim 11,
wherein the laser-light emitting element is configured to be driven at a plurality of light powers,
wherein the power detecting unit is configured to detect an average light power obtained by smoothening the light powers, and
wherein the approximate-expression updating unit is configured to update the approximate expression using the average light power.

14. The optical disc apparatus according to claim 11,
wherein the laser-light emitting element is configured to be driven at a plurality of light powers,
wherein the driving-current detecting unit is configured to detect an average driving current obtained by smoothening a plurality of driving currents corresponding to the light powers, and
wherein the approximate-expression updating unit is configured to update the approximate expression using the average driving current.

15. A laser driving device comprising:
a driving-current detecting unit configured to detect a driving current for driving a laser-light emitting element; and
a current driving unit configured to drive the laser-light emitting element on the basis of an input command driving current so that the laser-light emitting element outputs a target light power,
wherein an approximate expression indicating a driving-current to light-power characteristic of the laser-light emitting element is updated on the basis of the detected driving current and a power of light emitted from the laser-light emitting element to increase accuracy, the power being detected by an external power detecting unit, and
wherein the command driving current is configured to be calculated as a driving current corresponding to the target light power using the updated approximate expression.

16. The laser driving device according to claim 15, wherein the approximate expression is configured to be updated by updating a parameter thereof so as to decrease an error defined by a difference between the detected light power and an estimated light power, the error obtained by applying the detected driving current to the approximate expression.

17. The laser driving device according to claim 15,
wherein the laser-light emitting element is configured to be driven at a plurality of light powers,
wherein the power detecting unit is configured to detect an average light power obtained by smoothening the light powers, and
wherein the approximate expression is configured to be updated using the average light power.

18. The laser driving device according to claim 15,
wherein the laser-light emitting element is configured to be driven at a plurality of light powers,
wherein the driving-current detecting unit is configured to detect an average driving current obtained by smoothening a plurality of driving currents corresponding to the light powers, and
wherein the approximate expression is configured to be updated using the average driving current.
